(19) United States
(12) Patent Application Publication
(10) Pub. No.: US 2022/0049357 A1
(43) Pub. Date: Feb. 17, 2022

(54) SEMICONDUCTOR DEVICE AND METHOD OF MANUFACTURING SAME

(71) Applicant: Mitsubishi Electric Corporation, Chiyoda-ku, Tokyo (JP)

(72) Inventors: Masatoshi SUNAMOTO, Tokyo (JP); Ryuji UENO, Tokyo (JP); Misako KAWASUMI, Tokyo (JP)

(73) Assignee: Mitsubishi Electric Corporation, Chiyoda-ku, Tokyo (JP)

(21) Appl. No.: 17/431,262

(22) PCT Filed: Mar. 12, 2020
(86) PCT No.: PCT/JP2020/010858

§ 371 Date: Aug. 16, 2021

(30) Foreign Application Priority Data
Apr. 10, 2019 (JP) 2019-074474

(51) Int. Cl. C23C 18/54; C23C 18/16; C23C 18/36; H01L 21/288; H01L 23/00

(52) U.S. Cl. CPC C23C 18/54; C23C 18/1651; H01L 24/05; H01L 21/2885; C23C 18/36

(57) ABSTRACT

Provided is a semiconductor device, including: a front-back conduction-type semiconductor element; a front-side electrode formed on the front-back conduction-type semiconductor element; an electroless nickel-containing plating layer formed on the front-side electrode; and an electroless gold plating layer formed on the electroless nickel-containing plating layer, wherein the semiconductor device has a low-nickel concentration layer on a side of the electroless nickel-containing plating layer in contact with the electroless gold plating layer, and wherein the low-nickel concentration layer has a thickness smaller than that of the electroless gold plating layer.

### TECHNICAL FIELD

The present invention relates to a semiconductor device and a method of manufacturing the semiconductor device.

### BACKGROUND ART

A front-back conduction-type semiconductor element, particularly a power semiconductor element for power conversion typified by, for example, an insulated gate bipolar transistor (IGBT) or a diode has hitherto been mounted to a module by soldering a back-side electrode of the front-back conduction-type semiconductor element to a substrate, and subjecting a front-side electrode thereof to wire bonding. However, in recent years, from the viewpoints of shortening a manufacturing time period and reducing material cost, a mounting method involving directly soldering the front-side electrode of the front-back conduction-type semiconductor element and a metal electrode has increasingly been adopted. In this mounting method, a nickel film, a gold film, or the like having a thickness of several micrometers is required to be formed on the front-side electrode.

However, when a vacuum film formation method, such as vapor deposition or sputtering, is used to form a nickel film, a gold film, or the like, only a thickness of about 1.0 μm is generally obtained. When the thickness of the nickel film, the gold film, or the like is to be increased, manufacturing cost thereof is increased. In view of the foregoing, as a film formation method capable of increasing the thickness at low cost and at high speed, a plating technology has attracted attention.

Of such plating technologies, an electroless plating method, which is capable of selectively forming a plating layer only on a required part of a surface of an electrode without using a patterning process that utilizes a resist and a photomask, has been attracting particular attention. A low-cost zincate method is generally utilized as the electroless plating method. The zincate method involves: depositing zinc as catalyst nuclei on the surface of an electrode formed of aluminum or an aluminum alloy through displacement by aluminum; and then forming an electroless plating layer through the action of the catalyst nuclei.

For example, in Patent Document 1, there is a description that a nickel layer is formed on an aluminum electrode of a front-back conduction-type semiconductor element through use of an electroless plating method, and a gold layer is formed on the nickel layer. In Patent Document 1, there is a description of a known electroless plating method involving utilizing zincate treatment.

### CITATION LIST

### Patent Document

Patent Document 1: JP 2005-51084 A

### SUMMARY OF INVENTION

### Technical Problem

However, in the conventional art, there is a problem in that it is difficult to increase the thickness of a gold plating layer to be formed on an electrode of the front-back conduction-type semiconductor element. When the thickness of the gold plating layer is insufficient, there is a problem in that the wettability with solder is unsatisfactory when the front-back conduction-type semiconductor element is joined to a substrate, with the result that joining reliability becomes lower.

### Solution to Problem

Accordingly, the present invention has been made to solve the above-mentioned problem, and an object of the present invention is to provide a semiconductor device having high joining reliability and a method of manufacturing the semiconductor device by increasing the thickness of the gold plating layer to be formed on the electrode of the front-back conduction-type semiconductor element, to thereby improve the soldering quality at the time of mounting.

According to one embodiment of the present invention, there is provided a semiconductor device, including: a front-back conduction-type semiconductor element; a first electrode formed on the front-back conduction-type semiconductor element; an electroless nickel-containing plating layer formed on the first electrode; and an electroless gold plating layer formed on the electroless nickel-containing plating layer, wherein the semiconductor device has a low-nickel concentration layer on a side of the electroless nickel-containing plating layer in contact with the electroless gold plating layer, and the low-nickel concentration layer has a thickness smaller than a thickness of the electroless gold plating layer.

According to one embodiment of the present invention, there is provided a semiconductor device, including: a front-back conduction-type semiconductor element; a front-side electrode formed on the front-back conduction-type semiconductor element; an electroless nickel-containing plating layer formed on the front-side electrode; and an electroless gold plating layer formed on the electroless nickel-containing plating layer, wherein the semiconductor device has at least one kind of gold deposition-promoting element selected from the group consisting of bismuth, thallium, lead, and arsenic at an interface between the electroless nickel-containing plating layer and the electroless gold plating layer.

According to one embodiment of the present invention, there is provided a method of manufacturing a semiconductor device, including the steps of: forming a front-side electrode on one side of a front-back conduction-type semiconductor element; forming an electroless nickel-containing plating layer on the front-side electrode through use of an electroless nickel-containing plating solution; and forming an electroless gold plating layer on the electroless nickel-containing plating layer through use of an electroless gold plating solution, wherein the electroless nickel-containing plating solution contains at least one kind of gold deposition-promoting element selected from the group consisting of bismuth, thallium, lead, and arsenic.

### Advantageous Effects of Invention

According to the present invention, the semiconductor device having high joining reliability and the method of manufacturing the semiconductor device can be provided by improving the soldering quality when the front-back conduction-type semiconductor element is mounted.

### BRIEF DESCRIPTION OF DRAWINGS

FIG. 1 is a schematic sectional view of a semiconductor device according to a first embodiment.

FIG. 2 is a schematic sectional view of a semiconductor device according to a second embodiment.

FIG. 3 is a schematic sectional view of a semiconductor device according to a third embodiment.

FIG. 4 is a schematic sectional view of a semiconductor device according to a fourth embodiment.

### DESCRIPTION OF EMBODIMENTS

### First Embodiment

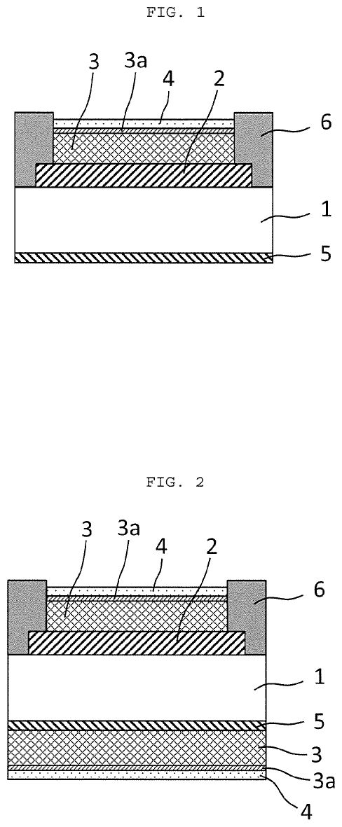

FIG. 1 is a schematic sectional view of a semiconductor device according to a first embodiment.

In FIG. 1, the semiconductor device according to this embodiment includes: a front-back conduction-type semiconductor element 1; a front-side electrode 2 formed on a front-side surface of the front-back conduction-type semiconductor element 1; an electroless nickel-containing plating layer 3 formed on the front-side electrode 2; an electroless gold plating layer 4 formed on the electroless nickel-containing plating layer 3; and a back-side electrode 5 formed on a back-side surface of the front-back conduction-type semiconductor element 1. A low-nickel concentration layer 3a is formed on a side of the electroless nickel-containing plating layer 3 in contact with the electroless gold plating layer 4. In addition, a protective film 6 is formed on the front-side surface of the front-back conduction-type semiconductor element 1 so as to surround the peripheries of the front-side electrode 2, the electroless nickel-containing plating layer 3, the low-nickel concentration layer 3a, and the electroless gold plating layer 4.

The electroless nickel-containing plating layer 3 is not particularly limited as long as the electroless nickel-containing plating layer 3 is formed by an electroless plating method involving using an electroless nickel-containing plating solution, but the layer is preferably formed of nickel phosphorus (NiP) or nickel boron (NiB).

The electroless gold plating layer 4 is not particularly limited as long as the electroless gold plating layer 4 is formed by an electroless plating method involving using an electroless gold plating solution.

In this embodiment, the low-nickel concentration layer 3a is defined as a layer having a nickel concentration that is lower by 0.1 mass % or more in a thickness direction than a nickel concentration in the vicinity of an interface between the electroless nickel-containing plating layer 3 and the front-side electrode 2 when the nickel concentration is measured in the thickness direction of a cross-section of the semiconductor device by energy dispersive X-ray spectroscopy (EDX). In the semiconductor device according to this embodiment, the thickness of the low-nickel concentration layer 3a is set to be smaller than that of the electroless gold plating layer 4. The thickness of each of the electroless nickel-containing plating layer 3 and the electroless gold plating layer 4 may be measured with a fluorescent X-ray thickness meter. From the viewpoint of obtaining high joining reliability, the thickness of the electroless nickel-containing plating layer 3 is preferably 0.5 μm or more and 10 μm or less, more preferably 2.0 μm or more and 6.0 μm or less. From the viewpoint of obtaining high joining reliability, the thickness of the electroless gold plating layer 4 is preferably 0.05 μm or more and 0.3 μm or less, more preferably 0.05 μm or more and 0.2 μm or less. The thickness of the low-nickel concentration layer 3a is more preferably 0.2 μm or less.

From the viewpoint that the low-nickel concentration layer 3a is easily formed so as to have a thickness smaller than that of the electroless gold plating layer 4, it is preferred that the low-nickel concentration layer 3a contain at least one kind of gold deposition-promoting element selected from the group consisting of bismuth (Bi), thallium (Tl), lead (Pb), and arsenic (As). The content of the gold deposition-promoting element in the low-nickel concentration layer 3a is not particularly limited, but an average value of the entirety of the low-nickel concentration layer 3a is preferably 0.01 ppm or more and 800 ppm or less. The content of the gold deposition-promoting element in the low-nickel concentration layer 3a may be measured by performing energy dispersive X-ray spectroscopy (EDX) or time-of-flight secondary ion mass spectrometry (TOF-SIMS) on a cross-section of the obtained semiconductor device.

The front-back conduction-type semiconductor element 1 is not particularly limited, and a known semiconductor element made of silicon (Si), silicon carbide (SiC), gallium arsenide (GaAs), gallium nitride (GaN), or the like may be used.

The front-side electrode 2 and the back-side electrode 5 are not particularly limited, and may each be formed of any electrode material known in the art, such as aluminum, an aluminum alloy, copper, nickel, or gold. The aluminum alloy is not particularly limited, and any alloy known in the art may be used. The aluminum alloy preferably contains an element nobler than aluminum. When the element nobler than aluminum is incorporated therein, at the time of performing zincate treatment, electrons easily flow out of aluminum present around the element, and hence dissolution of aluminum is promoted. Then, zinc is deposited in a concentrated manner in a portion in which aluminum has been dissolved out. As a result, the deposition amount of zinc serving as the origin of the formation of the electroless nickel-containing plating layer 3 is increased. Thus, the formation of the electroless nickel-containing plating layer 3 is facilitated. The element nobler than aluminum is not particularly limited, and examples thereof include iron, nickel, tin, lead, silicon, copper, silver, gold, tungsten, cobalt, platinum, palladium, iridium, and rhodium. The content of the element nobler than aluminum in the aluminum alloy is not particularly limited, but is preferably 5 mass % or less, more preferably 0.05 mass % or more and 3 mass % or less, still more preferably 0.1 mass % or more and 2 mass % or less.

In this embodiment, it is preferred, from the viewpoint of an excellent joining property, that the front-side electrode 2 be formed of aluminum, an aluminum alloy, or copper, and the back-side electrode 5 be formed of nickel or gold.

The thickness of the front-side electrode 2 is not particularly limited, but is generally 1 μm or more and 8 μm or less, preferably 2 μm or more and 7 μm or less, more preferably 3 μm or more and 6 μm or less.

The thickness of the back-side electrode 5 is not particularly limited, but is generally 0.1 μm or more and 4 μm or less, preferably 0.5 μm or more and 3 μm or less, more preferably 0.8 μm or more and 2 μm or less.

The protective film 6 is not particularly limited, and any protective film known in the art may be used. The protective film 6 is preferably a polyimide film, or a glass-based film containing silicon or the like because of its excellent heat resistance.

The semiconductor device having the above-mentioned structure may be manufactured in conformity with any method known in the art except for the steps of forming the electroless nickel-containing plating layer 3, the low-nickel concentration layer 3a, and the electroless gold plating layer 4.

Specifically, the semiconductor device may be manufactured as described below.

First, the front-side electrode 2 and the back-side electrode 5 are formed on the front-back conduction-type semiconductor element 1. The front-side electrode 2 is not formed in an outer edge portion on the front-side surface of the front-back conduction-type semiconductor element 1 so that a side surface of the front-side electrode 2 can be covered with the protective film 6. A method of forming the front-side electrode 2 and the back-side electrode 5 on the front-back conduction-type semiconductor element 1 is not particularly limited, and the formation may be performed in conformity with any method known in the art.

Next, in the outer edge portion on the front-side surface of the front-back conduction-type semiconductor element 1 and a part on the front-side electrode 2, the protective film 6 is formed. A method of forming the protective film 6 is not particularly limited, and the formation may be performed in conformity with any method known in the art.

Subsequently, plasma cleaning is performed on the front-side electrode 2 and the back-side electrode 5 formed on the front-back conduction-type semiconductor element 1. The purpose of the plasma cleaning is to remove an organic matter residue, a nitride, or an oxide firmly adhering to the front-side electrode 2 and the back-side electrode 5 through oxidative decomposition with plasma, to thereby ensure reactivity between the front-side electrode 2 and a plating pretreatment solution or a plating solution, and adhesiveness between the back-side electrode 5 and the protective film. The plasma cleaning is performed on both the front-side electrode 2 and the back-side electrode 5, but is preferably performed with emphasis on the front-side electrode 2. In addition, the order of the plasma cleaning is not particularly limited, but it is preferred that the plasma cleaning be performed on the back-side electrode 5 and then on the front-side electrode 2. This is because the protective film 6 including organic matter or the like is present on the front-side surface of the front-back conduction-type semiconductor element 1 together with the front-side electrode 2, and a residue from the protective film 6 often adheres to the front-side electrode 2. Here, the plasma cleaning needs to be performed so that the protective film 6 is not removed.

The conditions of the plasma cleaning step are not particularly limited, but are generally such that: an argon gas flow rate is 10 cc/min or more and 300 cc/min or less; an applied voltage is 200 W or more and 1,000 W or less; the degree of vacuum is 10 Pa or more and 100 Pa or less; and a treatment time period is 1 minute or more and 10 minutes or less.

Next, the protective film is attached to the plasma-cleaned back-side electrode 5 so that the back-side electrode 5 is not brought into contact with an electroless nickel-containing plating solution. The protective film may be stripped off after the drying of the front-back conduction-type semiconductor element 1 at a temperature of 60° C. or more and 150° C. or less for 15 minutes or more and 60 minutes or less after the formation of the electroless gold plating layer 4. The protective film is not particularly limited, and any known UV releasable tape used for protection in a plating step may be used. When the UV releasable tape is used as the protective film, the protective film can be released by irradiating a back surface of the front-back conduction-type semiconductor element 1 with UV rays after forming the electroless gold plating layer 4.

After the protective film is attached to the plasma-cleaned back-side electrode 5, the electroless nickel-containing plating layer 3 is formed on the front-side electrode 2 in a remaining portion in which the protective film 6 is not formed. When the front-side electrode 2 is formed of aluminum or an aluminum alloy, the electroless nickel-containing plating layer 3 is formed by a degreasing step, a pickling step, a first zincate treatment step, a zincate stripping step, a second zincate treatment step, and electroless nickel-containing plating treatment. When the front-side electrode 2 is formed of copper, the electroless nickel-containing plating layer 3 is formed by a degreasing step, a pickling step, palladium catalyst treatment, and electroless nickel-containing plating treatment. It is important to perform sufficient water washing between steps so that a treatment solution or a residue from a previous step is prevented from being brought over to a subsequent step.

In the degreasing step, degreasing is performed on the front-side electrode 2. The purpose of the degreasing is to remove organic matter, an oil and fat content, and an oxide film mildly adhering to the surface of the front-side electrode 2. The degreasing is generally performed by using an alkaline chemical solution having strong etching power against the front-side electrode 2. The oil and fat content is saponified through the degreasing step. In addition, out of unsaponifiable substances, an alkali-soluble substance is dissolved in the chemical solution, and an alkali-insoluble substance is lifted off through etching of the front-side electrode 2.

The conditions of the degreasing step are not particularly limited, but are generally such that: the pH of the alkaline chemical solution is 7.5 or more and 10.5 or less; the temperature is 45° C. or more and 75° C. or less; and a treatment time period is 30 seconds or more and 10 minutes or less.

In the pickling step, pickling is performed on the front-side electrode 2. The purpose of the pickling is to neutralize the surface of the front-side electrode 2 with sulfuric acid or other acids, and roughen the surface through etching, to thereby increase reactivity with treatment solutions in subsequent steps and increase the adhesive strength of plating materials.

The conditions of the pickling step are not particularly limited, but are generally such that: the temperature is 10° C. or more and 30° C. or less; and a treatment time period is 30 seconds or more and 2 minutes or less.

Subsequently, when the front-side electrode 2 is formed of aluminum or an aluminum alloy, it is preferred that the zincate treatment including the first zincate treatment step, the zincate stripping step, and the second zincate treatment step be performed before the electroless nickel-containing plating treatment. When the front-side electrode 2 is formed of copper, it is preferred that the palladium catalyst treatment be performed before the electroless nickel-containing plating treatment.

In the first zincate treatment step, zincate treatment is performed on the front-side electrode 2. The zincate treatment is treatment involving forming a zinc film while removing an oxide film through etching of the surface of the front-side electrode 2. In general, when the front-side electrode 2 is immersed in an aqueous solution in which zinc is dissolved (zincate treatment solution), aluminum is dissolved as ions because zinc has a nobler standard redox potential than that of aluminum or an aluminum alloy for forming the front-side electrode 2. Electrons generated at this time are received by zinc ions on the surface of the front-side electrode 2. Thus, a zinc film is formed on the surface of the front-side electrode 2.

In the zincate stripping step, the front-side electrode 2 having the zinc film formed on the surface is immersed in nitric acid so that zinc is dissolved.

In the second zincate treatment step, the front-side electrode 2 obtained by the zincate stripping step is immersed in a zincate treatment solution again. As a result, while aluminum and an oxide film thereof are removed, a zinc film is formed on the surface of the front-side electrode 2.

The reason why the above-mentioned zincate stripping step and second zincate treatment step are performed is that the surface of the front-side electrode 2 formed of aluminum or an aluminum alloy needs to be smoothened. When the number of repeating times of the zincate treatment step and the zincate stripping step is increased more, the surface of the front-side electrode 2 is smoothened more, and the uniform electroless nickel-containing plating layer 3 is formed. In consideration of surface smoothness, the zincate treatment is performed preferably twice or more, but in consideration of balance between surface smoothness and productivity, the zincate treatment is performed preferably twice or three times.

In the palladium catalyst treatment, the front-side electrode 2 is immersed in a palladium catalyst solution so that palladium is deposited on the front-side electrode 2 to form a palladium catalyst layer. The palladium catalyst layer is extremely chemically stable and is less susceptible to corrosion or other damage. Accordingly, in the subsequent electroless nickel-containing plating treatment, the front-side electrode 2 can be prevented from corrosion. The palladium catalyst solution is not particularly limited, and any solution known in the art may be used.

The concentration of palladium in the palladium catalyst solution is not particularly limited, but is generally 0.1 g/L or more and 2.0 g/L or less, preferably 0.3 g/L or more and 1.5 g/L or less. The pH of the palladium catalyst solution is not particularly limited, but is generally 1.0 or more and 3.5 or less, preferably 1.5 or more and 2.5 or less. The temperature of the palladium catalyst solution may be appropriately set depending on the kind of the palladium catalyst solution and the like, but is generally 30° C. or more and 80° C. or less, preferably 40° C. or more and 75° C. or less. The treatment time period may be appropriately set depending on the thickness of the palladium catalyst layer, but is generally 2 minutes or more and 30 minutes or less, preferably 5 minutes or more and 20 minutes or less.

In the electroless nickel-containing plating treatment step, the front-side electrode 2 is immersed in an electroless nickel-containing plating solution having, added thereto, at least one kind of gold deposition-promoting element selected from the group consisting of bismuth, thallium, lead, and arsenic so that the electroless nickel-containing plating layer 3 is formed thereon. When the front-side electrode 2 having the zinc film or the palladium catalyst layer formed thereon is immersed in the electroless nickel-containing plating solution, nickel is deposited on the front-side electrode 2 because zinc and palladium each have a baser standard redox potential than that of nickel. Subsequently, when the surface is coated with nickel, nickel is autocatalytically deposited by an action of a reducing agent (for example, a phosphorus compound-based reducing agent, such as hypophosphorous acid, or a boron compound-based reducing agent, such as dimethylamine borane) contained in the electroless nickel-containing plating solution. An element derived from the reducing agent and the gold deposition-promoting element are incorporated in the deposited nickel to form the electroless nickel-containing plating layer 3. The electroless nickel-containing plating solution is not particularly limited, and any solution known in the art having the gold deposition-promoting element added thereto may be used.

The concentration of nickel in the electroless nickel-containing plating solution is not particularly limited, but is generally 4.0 g/L or more and 7.0 g/L or less, preferably 4.5 g/L or more and 6.5 g/L or less. The concentration of the gold deposition-promoting element in the electroless nickel-containing plating solution is not particularly limited, but is preferably 0.01 ppm or more and 100 ppm or less, more preferably 0.05 ppm or more and 75 ppm or less. When bismuth is incorporated in the electroless nickel-containing plating solution, it is preferred that bismuth be added in the form of bismuth oxide or bismuth acetate. When thallium and arsenic are incorporated in the electroless nickel-containing plating solution, it is preferred that thallium and arsenic be each added in the form of a simple metal. When lead is incorporated in the electroless nickel-containing plating solution, it is preferred that lead be added in the form of lead oxide or lead acetate. The concentration of hypophosphorous acid in an electroless nickel-phosphorus plating solution is not particularly limited, but is generally 2 g/L or more and 30 g/L or less, preferably 10 g/L or more and 30 g/L or less. In addition, the concentration of dimethylamine borane in an electroless nickel-boron plating solution is not particularly limited, but is generally 0.2 g/L or more and 10 g/L or less, preferably 1 g/L or more and 10 g/L or less.

The pH of the electroless nickel-containing plating solution is not particularly limited, but is generally 4.0 or more and 6.0 or less, preferably 4.5 or more and 5.5 or less. The temperature of the electroless nickel-containing plating solution may be appropriately set depending on the kind of the electroless nickel-containing plating solution and the plating conditions, but is generally 70° C. or more and 90° C. or less, preferably 80° C. or more and 90° C. or less. A plating time period may be appropriately set depending on the plating conditions and the thickness of the electroless nickel-containing plating layer 3, but is generally 5 minutes or more and 40 minutes or less, preferably 10 minutes or more and 30 minutes or less.

Immediately before completion of the electroless nickel-containing plating treatment (a few minutes before), the gold deposition-promoting element can be segregated on a surface layer of the electroless nickel-containing plating layer 3 by increasing the supply amount of the electroless nickel-containing plating solution, increasing the stirring rate of the electroless nickel-containing plating solution, increasing the rocking of the electroless nickel-containing plating solution, or increasing the concentration of the gold deposition-promoting element in the electroless nickel-containing plating solution. In addition, when the front-back conduction-type semiconductor element 1 is pulled up from a plating tank after completion of the electroless nickel-containing plating treatment, the electroless nickel-containing plating solution having a low temperature may be brought into contact with a plating surface to segregate the gold deposition-promoting element on the surface layer of the electroless nickel-containing plating layer 3. In particular, bismuth and arsenic each have low solubility with respect to an aqueous solution, and hence are easily deposited when the temperature of the plating solution is low. Thus, it is preferred that the gold deposition-promoting element be segregated on the surface layer of the electroless nickel-containing plating layer 3 because the deposition of gold can be further promoted in an electroless gold plating treatment step to be described later.

In the electroless gold plating treatment step, the front-side electrode 2 having the electroless nickel-containing plating layer 3 formed thereon is immersed in the electroless gold plating solution so that the low-nickel concentration layer 3a and the electroless gold plating layer 4 are formed thereon. In the electroless gold plating treatment, for example, nickel in the electroless nickel-containing plating layer 3 is displaced by gold by an action of a complexing agent contained in an electroless gold displacement plating solution, and the deposition of gold is promoted from the gold deposition-promoting element of the electroless nickel-containing plating layer 3 serving as the origin. As a result, the electroless gold plating layer 4 is formed, and the low-nickel concentration layer 3a is formed on the side of the electroless nickel-containing plating layer 3 in contact with the electroless gold plating layer 4. When the surface of a conventional electroless nickel-containing plating layer is coated with gold, the displacement reaction between nickel and gold is stopped, and hence it is difficult to increase the thickness of the electroless gold plating layer. Accordingly, in the conventional art, the thickness of the electroless gold plating layer becomes smaller than that of the low-nickel concentration layer, and the thickness is about 0.05 μm at a maximum. In this embodiment, the gold deposition-promoting element is segregated on the surface layer of the electroless nickel-containing plating layer 3. Accordingly, the displacement reaction between nickel and gold is not stopped, and hence the thickness of the electroless gold plating layer 4 can be increased. Although the case in which the electroless gold displacement plating solution is used has been described above, an electroless gold reduction plating solution or the like may be used. The electroless gold plating solution is not particularly limited, and any solution known in the art may be used.

The concentration of gold in the electroless gold plating solution is not particularly limited, but is generally 0.3 g/L or more and 2.0 g/L or less, preferably 0.5 g/L or more and 2.0 g/L or less. The pH of the electroless gold plating solution is not particularly limited, but is generally 6.0 or more and 9.0 or less, preferably 6.5 or more and 8.0 or less. The temperature of the electroless gold plating solution may be appropriately set depending on the kind of the electroless gold plating solution and the plating conditions, but is generally 70° C. or more and 90° C. or less, preferably 80° C. or more and 90° C. or less. A plating time period may be appropriately set depending on the plating conditions and the thickness of the electroless gold plating layer 4, but is generally 5 minutes or more and 30 minutes or less, preferably 10 minutes or more and 20 minutes or less.

As required, the front-back conduction-type semiconductor element 1 after the electroless gold plating treatment is dried. Specifically, the front-back conduction-type semiconductor element may be rotated at a high speed to blow off water, and then placed in an oven and dried at 90° C. for 30 minutes.

According to the first embodiment, the soldering quality at the time of mounting of the front-back conduction-type semiconductor element can be improved, and hence a semiconductor device having high joining reliability and a method of manufacturing the semiconductor device can be provided.

### Second Embodiment

FIG. 2 is a schematic sectional view of a semiconductor device according to a second embodiment.

In FIG. 2, the semiconductor device according to this embodiment includes: the front-back conduction-type semiconductor element 1; the front-side electrode 2 formed on the front-side surface of the front-back conduction-type semiconductor element 1; the back-side electrode 5 formed on the back-side surface of the front-back conduction-type semiconductor element 1; the electroless nickel-containing plating layer 3 formed on each of the front-side electrode 2 and the back-side electrode 5; and the electroless gold plating layer 4 formed on each of the electroless nickel-containing plating layers 3. The low-nickel concentration layer 3a is formed on the side of each of the electroless nickel-containing plating layers 3 in contact with the corresponding electroless gold plating layer 4. In addition, the protective film 6 is arranged on the front-side surface of the front-back conduction-type semiconductor element 1 so as to surround the peripheries of the front-side electrode 2, the electroless nickel-containing plating layer 3, the low-nickel concentration layer 3a, and the electroless gold plating layer 4. That is, the semiconductor device according to this embodiment differs from the first embodiment in the point that the electroless nickel-containing plating layer 3, the low-nickel concentration layer 3a, and the electroless gold plating layer 4 are sequentially formed also on the back-side electrode 5.

As a method involving forming the electroless nickel-containing plating layer 3, the low-nickel concentration layer 3a, and the electroless gold plating layer 4 on the front-side electrode 2 and forming the electroless nickel-containing plating layer 3, the low-nickel concentration layer 3a, and the electroless gold plating layer 4 on the back-side electrode 5, the electroless plating treatment may be performed simultaneously on both the front-side electrode 2 and the back-side electrode 5 without attachment of the protective film to the back-side electrode 5. When the front-side electrode 2 and the back-side electrode 5 are each formed of aluminum or an aluminum alloy, the process of forming the electroless nickel-containing plating layer 3, the low-nickel concentration layer 3a, and the electroless gold plating layer 4 is performed by the degreasing step, the pickling step, the first zincate treatment step, the zincate stripping step, the second zincate treatment step, the electroless nickel-containing plating treatment, and the electroless gold plating treatment in the same manner as in the process described in the first embodiment, and hence the description thereof is omitted. In addition, when the front-side electrode 2 and the back-side electrode 5 are each formed of copper, the process of forming the electroless nickel-containing plating layer 3, the low-nickel concentration layer 3a, and the electroless gold plating layer 4 is performed by the degreasing step, the pickling step, the palladium catalyst treatment, the electroless nickel-containing plating treatment, and the electroless gold plating treatment in the same manner as in the process described in the first embodiment, and hence the description thereof is omitted.

According to the second embodiment, the soldering quality at the time of mounting of the front-back conduction-type semiconductor element can be improved, and hence a semiconductor device having high joining reliability and a method of manufacturing the semiconductor device can be provided.

### Third Embodiment

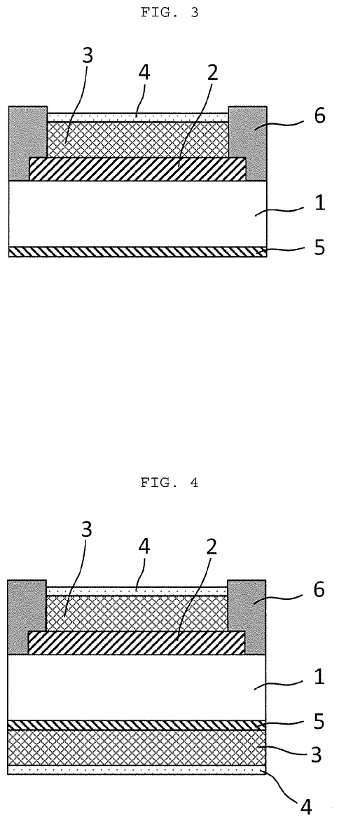

FIG. 3 is a schematic sectional view of a semiconductor device according to a third embodiment.

In FIG. 3, the semiconductor device according to this embodiment includes: the front-back conduction-type semiconductor element 1; the front-side electrode 2 formed on the front-side surface of the front-back conduction-type semiconductor element 1; the electroless nickel-containing plating layer 3 formed on the front-side electrode 2; the electroless gold plating layer 4 formed on the electroless nickel-containing plating layer 3; and the back-side electrode 5 formed on the back-side surface of the front-back conduction-type semiconductor element 1. At least one kind of gold deposition-promoting element selected from the group consisting of bismuth (Bi), thallium (Tl), lead (Pb), and arsenic (As) is present at least at the interface between the electroless nickel-containing plating layer 3 and the electroless gold plating layer 4. In addition, the protective film 6 is arranged on the front-side surface of the front-back conduction-type semiconductor element 1 so as to surround the peripheries of the front-side electrode 2, the electroless nickel-containing plating layer 3, and the electroless gold plating layer 4.

The electroless nickel-containing plating layer 3 is not particularly limited as long as the electroless nickel-containing plating layer 3 is formed by an electroless plating method involving using an electroless nickel-containing plating solution, but the layer is preferably formed of nickel phosphorus (NiP) or nickel boron (NiB).

The electroless gold plating layer 4 is not particularly limited as long as the electroless gold plating layer 4 is formed by an electroless plating method involving using an electroless gold plating solution.

In the semiconductor device according to this embodiment, at least one kind of gold deposition-promoting element selected from the group consisting of bismuth (Bi), thallium (Tl), lead (Pb), and arsenic (As) is present in the vicinity of the interface between the electroless nickel-containing plating layer 3 and the electroless gold plating layer 4. In this embodiment, the vicinity of the interface between the electroless nickel-containing plating layer 3 and the electroless gold plating layer 4 is defined as a region from the interface between the electroless nickel-containing plating layer 3 and the electroless gold plating layer 4 to a portion having a thickness of 0.2 μm toward the electroless nickel-containing plating layer 3. The content of the gold deposition-promoting element in the vicinity of the interface between the electroless nickel-containing plating layer 3 and the electroless gold plating layer 4 is not particularly limited, but an average value of the entirety of the vicinity of the interface is preferably 0.01 ppm or more and 800 ppm or less. The content of the gold deposition-promoting element may be measured by performing energy dispersive X-ray spectroscopy (EDX) or time-of-flight secondary ion mass spectrometry (TOF-SIMS) on a cross-section of the obtained semiconductor device. Further, the gold deposition-promoting element is present not only in the vicinity of the interface between the electroless nickel-containing plating layer 3 and the electroless gold plating layer 4, but also in the electroless nickel-containing plating layer 3 away from the vicinity of the interface. In the semiconductor device according to this embodiment, the electroless gold plating layer 4 is configured to be as thick as 0.05 μm or more and 0.3 μm or less. The thickness of each of the electroless nickel-containing plating layer 3 and the electroless gold plating layer 4 may be measured with a fluorescent X-ray thickness meter. From the viewpoint of obtaining high joining reliability, the thickness of the electroless nickel-containing plating layer 3 is preferably 0.5 μm or more and 10 μm or less, more preferably 2.0 μm or more and 6.0 μm or less. From the viewpoint of obtaining high joining reliability, the thickness of the electroless gold plating layer 4 is preferably 0.05 μm or more and 0.2 μm or less.

The front-back conduction-type semiconductor element 1 is not particularly limited, and a known semiconductor element made of silicon (Si), silicon carbide (SiC), gallium arsenide (GaAs), gallium nitride (GaN), or the like may be used.

The front-side electrode 2 and the back-side electrode 5 are not particularly limited, and may each be formed of any electrode material known in the art, such as aluminum, an aluminum alloy, copper, nickel, or gold. The aluminum alloy is not particularly limited, and any alloy known in the art may be used. The aluminum alloy preferably contains an element nobler than aluminum. When the element nobler than aluminum is incorporated therein, at the time of performing zincate treatment, electrons easily flow out of aluminum present around the element, and hence dissolution of aluminum is promoted. Then, zinc is deposited in a concentrated manner in a portion in which aluminum has been dissolved out. As a result, the deposition amount of zinc serving as the origin of the formation of the electroless nickel-containing plating layer 3 is increased. Thus, the formation of the electroless nickel-containing plating layer 3 is facilitated. The element nobler than aluminum is not particularly limited, and examples thereof include iron, nickel, tin, lead, silicon, copper, silver, gold, tungsten, cobalt, platinum, palladium, iridium, and rhodium. The content of the element nobler than aluminum in the aluminum alloy is not particularly limited, but is preferably 5 mass % or less, more preferably 0.05 mass % or more and 3 mass % or less, still more preferably 0.1 mass % or more and 2 mass % or less.

In this embodiment, it is preferred, from the viewpoint of an excellent joining property, that the front-side electrode 2 be formed of aluminum, an aluminum alloy, or copper, and the back-side electrode 5 be formed of nickel or gold.

The thickness of the front-side electrode 2 is not particularly limited, but is generally 1 μm or more and 8 μm or less, preferably 2 μm or more and 7 μm or less, more preferably 3 μm or more and 6 μm or less.

The thickness of the back-side electrode 5 is not particularly limited, but is generally 0.1 μm or more and 4 μm or less, preferably 0.5 μm or more and 3 μm or less, more preferably 0.8 μm or more and 2 μm or less.

The protective film 6 is not particularly limited, and any protective film known in the art may be used. The protective film 6 is preferably a polyimide film, or a glass-based film containing silicon or the like because of its excellent heat resistance.

The semiconductor device having the above-mentioned structure may be manufactured in conformity with any method known in the art except for the steps of forming the electroless nickel-containing plating layer 3 and the electroless gold plating layer 4.

Specifically, the semiconductor device may be manufactured as described below.

First, the front-side electrode 2 and the back-side electrode 5 are formed on the front-back conduction-type semiconductor element 1. The front-side electrode 2 is not formed in an outer edge portion on the front-side surface of the front-back conduction-type semiconductor element 1 so that a side surface of the front-side electrode 2 can be covered with the protective film 6. A method of forming the front-side electrode 2 and the back-side electrode 5 on the front-back conduction-type semiconductor element 1 is not particularly limited, and the formation may be performed in conformity with any method known in the art.

Next, in the outer edge portion on the front-side surface of the front-back conduction-type semiconductor element 1 and a part on the front-side electrode 2, the protective film 6 is formed. A method of forming the protective film 6 is not particularly limited, and the formation may be performed in conformity with any method known in the art.

Subsequently, plasma cleaning is performed on the front-side electrode 2 and the back-side electrode 5 formed on the front-back conduction-type semiconductor element 1. The purpose of the plasma cleaning is to remove an organic matter residue, a nitride, or an oxide firmly adhering to the front-side electrode 2 and the back-side electrode 5 through oxidative decomposition with plasma, to thereby ensure reactivity between the front-side electrode 2 and a plating pretreatment solution or a plating solution, and adhesiveness between the back-side electrode 5 and the protective film. The plasma cleaning is performed on both the front-side electrode 2 and the back-side electrode 5, but is preferably performed with emphasis on the front-side electrode 2. In addition, the order of the plasma cleaning is not particularly limited, but it is preferred that the plasma cleaning be performed on the back-side electrode 5 and then on the front-side electrode 2. This is because the protective film 6 including organic matter or the like is present on the front-side surface of the front-back conduction-type semiconductor element 1 together with the front-side electrode 2, and a residue from the protective film 6 often adheres to the front-side electrode 2. Here, the plasma cleaning needs to be performed so that the protective film 6 is not removed.

The conditions of the plasma cleaning step are not particularly limited, but are generally such that: an argon gas flow rate is 10 cc/min or more and 300 cc/min or less; an applied voltage is 200 W or more and 1,000 W or less; the degree of vacuum is 10 Pa or more and 100 Pa or less; and a treatment time period is 1 minute or more and 10 minutes or less.

Next, the protective film is attached to the plasma-cleaned back-side electrode 5 so that the back-side electrode 5 is not brought into contact with an electroless nickel-containing plating solution. The protective film may be stripped off after the drying of the front-back conduction-type semiconductor element 1 at a temperature of 60° C. or more and 150° C. or less for 15 minutes or more and 60 minutes or less after the formation of the electroless gold plating layer 4. The protective film is not particularly limited, and any known UV releasable tape used for protection in a plating step may be used. When the UV releasable tape is used as the protective film, the protective film can be released by irradiating a back surface of the front-back conduction-type semiconductor element 1 with UV rays after forming the electroless gold plating layer 4.

After the protective film is attached to the plasma-cleaned back-side electrode 5, the electroless nickel-containing plating layer 3 is formed on the front-side electrode 2 in a remaining portion in which the protective film 6 is not formed. The electroless nickel-containing plating layer 3 is formed by a degreasing step, a pickling step, a first zincate treatment step, a zincate stripping step, a second zincate treatment step, and electroless nickel-containing plating treatment, or by a degreasing step, a pickling step, palladium catalyst treatment, and electroless nickel-containing plating treatment. It is important to perform sufficient water washing between steps so that a treatment solution or a residue from a previous step is prevented from being brought over to a subsequent step.

In the degreasing step, degreasing is performed on the front-side electrode 2. The purpose of the degreasing is to remove organic matter, an oil and fat content, and an oxide film mildly adhering to the surface of the front-side electrode 2. The degreasing is generally performed by using an alkaline chemical solution having strong etching power against the front-side electrode 2. The oil and fat content is saponified through the degreasing step. In addition, out of unsaponifiable substances, an alkali-soluble substance is dissolved in the chemical solution, and an alkali-insoluble substance is lifted off through etching of the front-side electrode 2.

The conditions of the degreasing step are not particularly limited, but are generally such that: the pH of the alkaline chemical solution is 7.5 or more and 10.5 or less; the temperature is 45° C. or more and 75° C. or less; and a treatment time period is 30 seconds or more and 10 minutes or less.

In the pickling step, pickling is performed on the front-side electrode 2. The purpose of the pickling is to neutralize the surface of the front-side electrode 2 with sulfuric acid or other acids, and roughen the surface through etching, to thereby increase reactivity with treatment solutions in subsequent steps and increase the adhesive strength of plating materials.

The conditions of the pickling step are not particularly limited, but are generally such that: the temperature is 10° C. or more and 30° C. or less; and a treatment time period is 30 seconds or more and 2 minutes or less.

Subsequently, when the front-side electrode 2 is formed of aluminum or an aluminum alloy, it is preferred that zincate treatment including the first zincate treatment step, the zincate stripping step, and the second zincate treatment step be performed before the electroless nickel-containing plating treatment. When the front-side electrode 2 is formed of copper, it is preferred that the palladium catalytic treatment be performed before the electroless nickel-containing plating treatment.

In the first zincate treatment step, zincate treatment is performed on the front-side electrode 2. The zincate treatment is treatment involving forming a zinc film while removing an oxide film through etching of the surface of the front-side electrode 2. In general, when the front-side electrode 2 is immersed in an aqueous solution in which zinc is dissolved (zincate treatment solution), aluminum is dissolved as ions because zinc has a nobler standard redox potential than that of aluminum or an aluminum alloy for forming the front-side electrode 2. Electrons generated at this time are received by zinc ions on the surface of the front-side electrode 2. Thus, a zinc film is formed on the surface of the front-side electrode 2.

In the zincate stripping step, the front-side electrode 2 having the zinc film formed on the surface is immersed in nitric acid so that zinc is dissolved.

In the second zincate treatment step, the front-side electrode 2 obtained by the zincate stripping step is immersed in a zincate treatment solution again. Thus, while aluminum and an oxide film thereof are removed, a zinc film is formed on the surface of the front-side electrode 2.

The reason why the above-mentioned zincate stripping step and second zincate treatment step are performed is that the surface of the front-side electrode 2 formed of aluminum or an aluminum alloy needs to be smoothened. When the number of repeating times of the zincate treatment step and the zincate stripping step is increased more, the surface of the front-side electrode 2 is smoothened more, and the uniform electroless nickel-containing plating layer 3 is formed. In consideration of surface smoothness, the zincate treatment is performed preferably twice or more, but in consideration of balance between surface smoothness and productivity, the zincate treatment is performed preferably twice or three times.

In the palladium catalyst treatment, the front-side electrode 2 is immersed in a palladium catalyst solution so that palladium is deposited on the front-side electrode 2 to form a palladium catalyst layer. The palladium catalyst layer is extremely chemically stable and is less susceptible to corrosion or other damage. Accordingly, in the subsequent electroless nickel-containing plating treatment, the front-side electrode 2 can be prevented from corrosion. The palladium catalyst solution is not particularly limited, and any solution known in the art may be used.

The concentration of palladium in the palladium catalyst solution is not particularly limited, but is generally 0.1 g/L or more and 2.0 g/L or less, preferably 0.3 g/L or more and 1.5 g/L or less. The pH of the palladium catalyst solution is not particularly limited, but is generally 1.0 or more and 3.5 or less, preferably 1.5 or more and 2.5 or less. The temperature of the palladium catalyst solution may be appropriately set depending on the kind of the palladium catalyst solution and the like, but is generally 40° C. or more and 80° C. or less, preferably 45° C. or more and 75° C. or less. The treatment time period may be appropriately set depending on the thickness of the palladium catalyst layer, but is generally 2 minutes or more and 30 minutes or less, preferably 5 minutes or more and 20 minutes or less.

In the electroless nickel-containing plating treatment step, the front-side electrode 2 is immersed in an electroless nickel-containing plating solution having, added thereto, at least one kind of gold deposition-promoting element selected from the group consisting of bismuth, thallium, lead, and arsenic so that the electroless nickel-containing plating layer 3 is formed thereon. When the front-side electrode 2 having the zinc film or the palladium catalyst layer formed thereon is immersed in the electroless nickel-containing plating solution, nickel is deposited on the front-side electrode 2 because zinc and palladium each have a baser standard redox potential than that of nickel. Subsequently, when the surface is coated with nickel, nickel is autocatalytically deposited by an action of a reducing agent (for example, a phosphorus compound-based reducing agent, such as hypophosphorous acid, or a boron compound-based reducing agent, such as dimethylamine borane) contained in the electroless nickel-containing plating solution. An element derived from the reducing agent and the gold deposition-promoting element are incorporated in the deposited nickel to form the electroless nickel-containing plating layer 3. The electroless nickel-containing plating solution is not particularly limited, and any solution known in the art having the gold deposition-promoting element added thereto may be used.

The concentration of nickel in the electroless nickel-containing plating solution is not particularly limited, but is generally 4.0 g/L or more and 7.0 g/L or less, preferably 4.5 g/L or more and 6.5 g/L or less. The concentration of the gold deposition-promoting element in the electroless nickel-containing plating solution is not particularly limited, but is preferably 0.01 ppm or more and 100 ppm or less, more preferably 0.05 ppm or more and 75 ppm or less. When bismuth is incorporated in the electroless nickel-containing plating solution, it is preferred that bismuth be added in the form of bismuth oxide or bismuth acetate. When thallium and arsenic are incorporated in the electroless nickel-containing plating solution, it is preferred that thallium and arsenic be each added in the form of a simple metal. When lead is incorporated in the electroless nickel-containing plating solution, it is preferred that lead be added in the form of lead oxide or lead acetate. The concentration of hypophosphorous acid in an electroless nickel-phosphorus plating solution is not particularly limited, but is generally 2 g/L or more and 30 g/L or less, preferably 10 g/L or more and 20 g/L or less. In addition, the concentration of dimethylamine borane in an electroless nickel-boron plating solution is not particularly limited, but is generally 0.2 g/L or more and 10 g/L or less, preferably 1 g/L or more and 5 g/L or less.

The pH of the electroless nickel-containing plating solution is not particularly limited, but is generally 4.0 or more and 6.0 or less, preferably 4.5 or more and 5.5 or less. The temperature of the electroless nickel-containing plating solution may be appropriately set depending on the kind of the electroless nickel-containing plating solution and the plating conditions, but is generally 70° C. or more and 90° C. or less, preferably 80° C. or more and 90° C. or less. A plating time period may be appropriately set depending on the plating conditions and the thickness of the electroless nickel-containing plating layer 3, but is generally 5 minutes or more and 40 minutes or less, preferably 10 minutes or more and 30 minutes or less.

Immediately before completion of the electroless nickel-containing plating treatment (a few minutes before), the gold deposition-promoting element can be segregated on a surface layer of the electroless nickel-containing plating layer 3 by increasing the supply amount of the electroless nickel-containing plating solution, increasing the stirring rate of the electroless nickel-containing plating solution, increasing the rocking of the electroless nickel-containing plating solution, or increasing the concentration of the gold deposition-promoting element in the electroless nickel-containing plating solution. In addition, when the front-back conduction-type semiconductor element 1 is pulled up from a plating tank after completion of the electroless nickel-containing plating treatment, the electroless nickel-containing plating solution having a low temperature may be brought into contact with a plating surface to segregate the gold deposition-promoting element on the surface layer of the electroless nickel-containing plating layer 3. In particular, bismuth and arsenic each have low solubility with respect to an aqueous solution, and hence are easily deposited when the temperature of the plating solution is low. Thus, it is preferred that the gold deposition-promoting element be segregated on the surface layer of the electroless nickel-containing plating layer 3 because the deposition of gold can be further promoted in an electroless gold plating treatment step to be described later.

In the electroless gold plating treatment step, the front-side electrode 2 having the electroless nickel-containing plating layer 3 formed thereon is immersed in the electroless gold plating solution so that the electroless gold plating layer 4 is formed thereon. In the electroless gold plating treatment, for example, nickel in the electroless nickel-containing plating layer 3 is displaced by gold by an action of a complexing agent contained in an electroless gold displacement plating solution, and the deposition of gold is promoted from the gold deposition-promoting element of the electroless nickel-containing plating layer 3 serving as the origin. As a result, the electroless gold plating layer 4 is formed, and the gold deposition-promoting element is present in the vicinity of the interface between the electroless nickel-containing plating layer 3 and the electroless gold plating layer 4. When the surface of a conventional electroless nickel-containing plating layer is coated with gold, the displacement reaction between nickel and gold is stopped, and hence it is difficult to increase the thickness of the electroless gold plating layer. Accordingly, in the conventional art, the thickness of the electroless gold plating layer is about 0.05 μm at a maximum. In this embodiment, the gold deposition-promoting element is segregated on the surface layer of the electroless nickel-containing plating layer 3. Accordingly, the displacement reaction between nickel and gold is not stopped, and hence the thickness of the electroless gold plating layer 4 can be increased. Although the case in which the electroless gold displacement plating solution is used has been described above, an electroless gold reduction plating solution or the like may be used. The electroless gold plating solution is not particularly limited, and any solution known in the art may be used.

The concentration of gold in the electroless gold plating solution is not particularly limited, but is generally 0.3 g/L or more and 2.0 g/L or less, preferably 0.5 g/L or more and 2.0 g/L or less. The pH of the electroless gold plating solution is not particularly limited, but is generally 6.0 or more and 9.0 or less, preferably 6.5 or more and 8.0 or less. The temperature of the electroless gold plating solution may be appropriately set depending on the kind of the electroless gold plating solution and the plating conditions, but is generally 70° C. or more and 90° C. or less, preferably 80° C. or more and 90° C. or less. A plating time period may be appropriately set depending on the plating conditions and the thickness of the electroless gold plating layer 4, but is generally 5 minutes or more and 30 minutes or less, preferably 10 minutes or more and 20 minutes or less.

As required, the front-back conduction-type semiconductor element 1 after the electroless gold plating treatment is dried. Specifically, the front-back conduction-type semiconductor element may be rotated at a high speed to blow off water, and then placed in an oven and dried at 90° C. for 30 minutes.

According to the third embodiment, the soldering quality at the time of mounting of the front-back conduction-type semiconductor element can be improved, and hence a semiconductor device having high joining reliability and a method of manufacturing the semiconductor device can be provided.

### Fourth Embodiment

FIG. 4 is a schematic sectional view of a semiconductor device according to a fourth embodiment.

In FIG. 4, the semiconductor device according to this embodiment includes: the front-back conduction-type semiconductor element 1; the front-side electrode 2 formed on the front-side surface of the front-back conduction-type semiconductor element 1; the back-side electrode 5 formed on the back-side surface of the front-back conduction-type semiconductor element 1; the electroless nickel-containing plating layer 3 formed on each of the front-side electrode 2 and the back-side electrode 5; and the electroless gold plating layers 4 formed on the respective electroless nickel-containing plating layers 3. At least one kind of gold deposition-promoting element selected from the group consisting of bismuth (Bi), thallium (Ti), lead (Pb), and arsenic (As) is present at least at the interface between each of the electroless nickel-containing plating layers 3 and the corresponding electroless gold plating layer 4. In addition, the protective film 6 is arranged on the front-side electrode 2 in which the electroless nickel-containing plating layer 3 is not formed so as to surround the peripheries of the electroless nickel-containing plating layer 3 and the electroless gold plating layer 4 formed on the front-side electrode 2. That is, the semiconductor device according to this embodiment differs from the third embodiment in the point that the electroless nickel-containing plating layer 3 and the electroless gold plating layer 4 are sequentially formed also on the back-side electrode 5, and at least one kind of gold deposition-promoting element selected from the group consisting of bismuth (Bi), thallium (Ti), lead (Pb), and arsenic (As) is present in the vicinity of the interface between those layers.

As a method involving forming the electroless nickel-containing plating layer 3 and the electroless gold plating layer 4 on the front-side electrode 2 and forming the electroless nickel-containing plating layer 3 and the electroless gold plating layer 4 on the back-side electrode 5, the electroless plating treatment may be performed simultaneously on both the front-side electrode 2 and the back-side electrode 5 without attachment of the protective film to the back-side electrode 5. When the front-side electrode 2 and the back-side electrode 5 are each formed of aluminum or an aluminum alloy, the process of forming the electroless nickel-containing plating layer 3 and the electroless gold plating layer 4 is performed by the degreasing step, the pickling step, the first zincate treatment step, the zincate stripping step, the second zincate treatment step, the electroless nickel-containing plating treatment, and the electroless gold plating treatment in the same manner as in the process described in the third embodiment, and hence the description thereof is omitted. In addition, when the front-side electrode 2 and the back-side electrode 5 are each formed of copper, the process of forming the electroless nickel-containing plating layer 3 and the electroless gold plating layer 4 is performed by the degreasing step, the pickling step, the palladium catalyst treatment, the electroless nickel-containing plating treatment, and the electroless gold plating treatment in the same manner as in the process described in the third embodiment, and hence the description thereof is omitted.

According to the fourth embodiment, the soldering quality at the time of mounting of the front-back conduction-type semiconductor element can be improved, and hence a semiconductor device having high joining reliability and a method of manufacturing the semiconductor device can be provided.

The semiconductor devices of the above-mentioned embodiments may each be manufactured by subjecting a chip (front-back conduction-type semiconductor element 1) obtained through dicing of a semiconductor wafer to the plating treatments, or, from the viewpoint of productivity or the like, may each be manufactured by subjecting the semiconductor wafer to the plating treatments, followed by dicing. In particular, in recent years, from the viewpoint of improving the electrical characteristics of the semiconductor device, a reduction in thickness of the front-back conduction-type semiconductor element 1 has been required, and handling becomes sometimes difficult unless the semiconductor wafer has a larger thickness in its periphery than in its center. With the above-mentioned plating treatments, desired plating layers can be formed even on such semiconductor wafer having different thicknesses in its center and in its periphery.

In each of the above-mentioned first to fourth embodiments, the description has been made of the case in which the front-side electrode and the back-side electrode are formed on the front-back conduction-type semiconductor element, and then the electroless nickel-containing plating layer and the electroless gold plating layer are formed. However, a timing at which the back-side electrode is formed is not particularly limited. The effect of the present invention can be obtained regardless of the timing at which the back-side electrode is formed. For example, the following is possible: the front-side electrode is formed on one side of the front-back conduction-type semiconductor element, the electroless nickel-containing plating layer and the electroless gold plating layer are formed on the front-side electrode, and then the back-side electrode is formed on the remaining other side of the front-back conduction-type semiconductor element.

### EXAMPLES

The present invention is hereinafter described in detail by way of Examples. However, the present invention is by no means limited thereto.

### Example 1

In Example 1, a semiconductor device having a configuration illustrated in FIG. 1 was produced.

First, a Si semiconductor element (14 mm×14 mm×70 μm thick) was prepared as the front-back conduction-type semiconductor element 1.

Next, on a front-side surface of the Si semiconductor element, an aluminum alloy electrode (silicon content: about 1 mass %, thickness: 5.0 μm) serving as the front-side electrode 2 was formed, and on a back-side surface of the Si semiconductor element, an electrode in which an aluminum alloy layer (silicon content: about 1 mass %, thickness: 1.3 μm), a nickel layer (thickness: 1.0 μm), and a gold layer (thickness: 0.03 μm) were laminated from the Si semiconductor element side, the electrode serving as the back-side electrode 5, was formed. After that, the protective film 6 (polyimide, thickness: 8 μm) was formed in a part on the front-side electrode 2.

Next, steps were performed under the conditions shown in Table 1 below to sequentially form, on the front-side electrode 2, the electroless nickel-containing plating layer 3, the low-nickel concentration layer 3a, and the electroless gold plating layer 4. Thus, the semiconductor device was obtained. Water washing involving using pure water was performed between the steps.

TABLE 1

| | Step | Conditions etc. |
|---|---|---|
| 1 | Plasma cleaning | Ar flow rate: 100 cc/min, applied |
| | | voltage: 800 W, 2 min, degree of |
| | | vacuum: 10 Pa |
| 2 | Attachment of | Attachment of UV releasable tape to |
| | protective film | back-side electrode |
| 3 | Degreasing | Alkaline degreasing solution, pH = 9.5, |
| | | 70° C., 3 min |
| 4 | Pickling | 10% Sulfuric acid, 30° C., 1 min |
| 5 | First zincate | Alkaline zincate treatment solution, |
| | treatment | pH = 12, 25° C., 20 sec |
| 6 | Zincate stripping | Nitric acid, 25° C., 15 sec |
| 7 | Second zincate | Alkaline zincate treatment solution, |
| | treatment | pH = 12, 25° C., 20 sec |
| 8 | Electroless | Acidic electroless nickel-phosphorus |
| | nickel-phosphorus | plating solution, pH = 5.0, Bi |
| | plating treatment | concentration: 50 ppm, |
| | | 85° C., 25 min, liquid circulation speed |
| | | ratio: 2 turns/25 min |
| 9 | Electroless | Acidic electroless nickel-phosphorus |
| | nickel-phosphorus | plating solution, pH = 5.0, Bi |
| | plating treatment | concentration: 50 ppm, |
| | | 85° C., 2 min, liquid circulation speed |
| | | ratio: 16 turns/25 min |
| 10 | Electroless gold | Electroless gold displacement plating |
| | plating treatment | solution, pH = 7.0, 90° C., 30 min |

The thicknesses of the electroless nickel-containing plating layer 3 and the electroless gold plating layer 4 in the obtained semiconductor device were each measured with a commercially available fluorescent X-ray thickness meter. As a result, the electroless nickel-containing plating layer 3 had a thickness of 5.0 μm, and the electroless gold plating layer 4 had a thickness of 0.13 μm. The thickness and bismuth concentration of the low-nickel concentration layer 3a in the semiconductor device were measured with a commercially available energy dispersive X-ray spectrometer. As a result, the low-nickel concentration layer 3a had a thickness of 0.02 μm and a bismuth concentration of 600 ppm on average.

As a result of directly soldering a metal electrode to the electroless gold plating layer 4 of the obtained semiconductor device in order to simulate the mounting step, the soldering quality was satisfactory. It is conceivable from the foregoing that the semiconductor device having high joining reliability was able to be manufactured.

### Example 2

In Example 2, a semiconductor device having a configuration illustrated in FIG. 2 was produced.

First, a Si semiconductor element (14 mm×14 mm×70 μm thick) was prepared as the front-back conduction-type semiconductor element 1.

Next, on a front-side surface of the Si semiconductor element, an aluminum alloy electrode (silicon content: about 1 mass %, thickness: 5.0 μm) serving as the front-side electrode 2 was formed, and on a back-side surface of the Si semiconductor element, an aluminum alloy electrode (silicon content: about 1 mass %, thickness: 1.5 μm) serving as the back-side electrode 5 was formed. After that, the protective film 6 (polyimide, thickness: 8 μm) was formed in a part on the front-side electrode 2.

Next, steps were performed under the conditions shown in Table 2 below to sequentially form, on the front-side electrode 2, the electroless nickel-containing plating layer 3, the low-nickel concentration layer 3a, and the electroless gold plating layer 4, and to sequentially form, on the back-side electrode 5, the electroless nickel-containing plating layer 3, the low-nickel concentration layer 3a, and the electroless gold plating layer 4. Thus, the semiconductor device was obtained. Water washing involving using pure water was performed between the steps.

TABLE 2

| | Step | Conditions etc. |
|---|---|---|
| 1 | Plasma cleaning | Ar flow rate: 100 cc/min, applied |
| | | voltage: 800 W, 2 min, degree of |
| | | vacuum: 10 Pa |
| 2 | Degreasing | Alkaline degreasing solution, pH = 9.5, |
| | | 70° C., 3 min |
| 3 | Pickling | 10% Sulfuric acid, 30° C., 1 min |
| 4 | First zincate | Alkaline zincate treatment solution, |
| | treatment | pH = 12, 25° C., 20 sec |
| 5 | Zincate stripping | Nitric acid, 25° C., 15 sec |
| 6 | Second zincate | Alkaline zincate treatment solution, |
| | treatment | pH = 12, 25° C., 20 sec |
| 7 | Electroless | Acidic electroless nickel-phosphorus |
| | nickel-phosphorus | plating solution, pH = 5.0, Bi |
| | plating treatment | concentration: 50 ppm, |
| | | 85° C., 25 min, liquid circulation speed |
| | | ratio: 2 turns/25 min |
| 8 | Electroless | Acidic electroless nickel-phosphorus |
| | nickel-phosphorus | plating solution, pH = 5.0, Bi |
| | plating treatment | concentration: 50 ppm, |
| | | 85° C., 2 min, liquid circulation speed |
| | | ratio: 16 turns/25 min |
| 9 | Electroless gold | Electroless gold displacement plating |
| | plating treatment | solution, pH = 7.0, 90° C., 30 min |

The thicknesses of the electroless nickel-containing plating layer 3 and the electroless gold plating layer 4 in the obtained semiconductor device were each measured with a commercially available fluorescent X-ray thickness meter. As a result, the electroless nickel-containing plating layer 3 formed on the front-side electrode 2 had a thickness of 5.0 μm, and the electroless gold plating layer 4 formed on the front-side electrode 2 had a thickness of 0.13 μm. The electroless nickel-containing plating layer 3 formed on the back-side electrode 5 had a thickness of 5.1 μm, and the electroless gold plating layer 4 formed on the back-side electrode 5 had a thickness of 0.13 μm. The thickness and bismuth concentration of the low-nickel concentration layer 3a in the semiconductor device were measured with a commercially available energy dispersive X-ray spectrometer. As a result, the low-nickel concentration layer 3a formed on the front-side electrode 2 had a thickness of 0.03 μm and a bismuth concentration of 600 ppm on average. The low-nickel concentration layer 3a formed on the back-side electrode 5 had a thickness of 0.02 μm and a bismuth concentration of 600 ppm on average.

As a result of directly soldering a metal electrode to the electroless gold plating layer 4 of the obtained semiconductor device in order to simulate the mounting step, the soldering quality was satisfactory. It is conceivable from the foregoing that the semiconductor device having high joining reliability was able to be manufactured.

### Example 3

In Example 3, a semiconductor device having a configuration illustrated in FIG. 3 was produced.

First, a Si semiconductor element (14 mm×14 mm×70 μm thick) was prepared as the front-back conduction-type semiconductor element 1.

Next, on a front-side surface of the Si semiconductor element, a copper electrode (thickness: 5.0 μm) serving as the front-side electrode 2 was formed, and on a back-side surface of the Si semiconductor element, an electrode in which an aluminum alloy electrode (silicon content: about 1 mass %, thickness: 1.3 μm), a nickel layer (thickness: 1.0 μm), and a gold layer (thickness: 0.03 μm) were laminated from the Si semiconductor element side, the electrode serving as the back-side electrode 5, was formed. After that, the protective film 6 (polyimide, thickness: 8 μm) was formed in a part on the front-side electrode 2.

Next, steps were performed under the conditions shown in Table 3 below to sequentially form, on the front-side electrode 2, the electroless nickel-containing plating layer 3, the low-nickel concentration layer 3a, and the electroless gold plating layer 4. Thus, the semiconductor device was obtained. Water washing involving using pure water was performed between the steps.

TABLE 3

| | Step | Conditions etc. |
|---|---|---|
| 1 | Plasma cleaning | Ar flow rate: 100 cc/min, applied |
| | | voltage: 800 W, 2 min, degree of |
| | | vacuum: 10 Pa |
| 2 | Attachment of | Attachment of UV releasable tape to |
| | protective film | back-side electrode |
| 3 | Degreasing | Alkaline degreasing solution, pH = 9.5, |
| | | 70° C., 3 min |
| 4 | Pickling | 10% Sulfuric acid, 30° C., 1 min |
| 5 | Palladium | Palladium catalyst solution, pH = 2.0, |
| | catalyst | 50° C., 15 min |
| | treatment | |
| 6 | Electroless | Acidic electroless nickel-phosphorus |
| | nickel-phosphorus | plating solution, pH = 5.0, Bi |
| | plating treatment | concentration: 50 ppm, |
| | | 85° C., 25 min, liquid circulation speed |
| | | ratio: 2 turns/25 min |
| 7 | Electroless | Acidic electroless nickel-phosphorus |
| | nickel-phosphorus | plating solution, pH = 5.0, Bi |
| | plating treatment | concentration: 50 ppm, |
| | | 85° C., 2 min, liquid circulation speed |
| | | ratio: 16 turns/25 min |
| 8 | Electroless gold | Electroless gold displacement plating |
| | plating treatment | solution, pH = 7.0, 90° C., 30 min |

The thicknesses of the electroless nickel-containing plating layer 3 and the electroless gold plating layer 4 in the obtained semiconductor device were each measured with a commercially available fluorescent X-ray thickness meter. As a result, the electroless nickel-containing plating layer 3 had a thickness of 5.0 μm, and the electroless gold plating layer 4 had a thickness of 0.13 μm. The thickness and bismuth concentration of the low-nickel concentration layer 3a in the semiconductor device were measured with a commercially available energy dispersive X-ray spectrometer. As a result, the low-nickel concentration layer 3a had a thickness of 0.02 μm and a bismuth concentration of 600 ppm on average.

As a result of directly soldering a metal electrode to the electroless gold plating layer 4 of the obtained semiconductor device in order to simulate the mounting step, the soldering quality was satisfactory. It is conceivable from the foregoing that the semiconductor device having high joining reliability was able to be manufactured.

### Example 4

In Example 4, a semiconductor device having a configuration illustrated in FIG. 4 was produced.

First, a Si semiconductor element (14 mm×14 mm×70 μm thick) was prepared as the front-back conduction-type semiconductor element 1.

Next, on a front-side surface of the Si semiconductor element, a copper electrode (thickness: 5.0 μm) serving as the front-side electrode 2 was formed, and on a back-side surface of the Si semiconductor element, another copper electrode (thickness: 5.0 μm) serving as the back-side electrode 5 was formed. After that, the protective film 6 (polyimide, thickness: 8 μm) was formed in a part on the front-side electrode 2.

Next, steps were performed under the conditions shown in Table 4 below to sequentially form, on the front-side electrode 2, the electroless nickel-containing plating layer 3, the low-nickel concentration layer 3a, and the electroless gold plating layer 4, and to sequentially form, on the back-side electrode 5, the electroless nickel-containing plating layer 3, the low-nickel concentration layer 3a, and the electroless gold plating layer 4. Thus, the semiconductor device was obtained. Water washing involving using pure water was performed between the steps.

TABLE 4

| | Step | Conditions etc. |
|---|---|---|
| 1 | Plasma cleaning | Ar flow rate: 100 cc/min, applied |
| | | voltage: 800 W, 2 min, degree of |
| | | vacuum: 10 Pa |
| 2 | Degreasing | Alkaline degreasing solution, pH = 9.5, |
| | | 70° C., 3 min |
| 3 | Pickling | 10% Sulfuric acid, 30° C., 1 min |
| 4 | Palladium | Palladium catalyst solution, pH = 2.0, |
| | catalyst | 50° C., 15 min |
| | treatment | |
| 5 | Electroless | Acidic electroless nickel-phosphorus |
| | nickel-phosphorus | plating solution, pH = 5.0, Bi |
| | plating treatment | concentration: 50 ppm, |
| | | 85° C., 25 min, liquid circulation speed |
| | | ratio: 2 turns/25 min |
| 6 | Electroless | Acidic electroless nickel-phosphorus |
| | nickel-phosphorus | plating solution, pH = 5.0, Bi |
| | plating treatment | concentration: 50 ppm, |
| | | 85° C., 2 min, liquid circulation speed |
| | | ratio: 16 turns/25 min |
| 7 | Electroless gold | Electroless gold displacement plating |
| | plating treatment | solution, pH = 7.0, 90° C., 30 min |

The thicknesses of the electroless nickel-containing plating layer 3 and the electroless gold plating layer 4 in the obtained semiconductor device were each measured with a commercially available fluorescent X-ray thickness meter. As a result, the electroless nickel-containing plating layer 3 formed on the front-side electrode 2 had a thickness of 5.0 μm, and the electroless gold plating layer 4 formed on the front-side electrode 2 had a thickness of 0.13 μm. The electroless nickel-containing plating layer 3 formed on the back-side electrode 5 had a thickness of 4.7 μm, and the electroless gold plating layer 4 formed on the back-side electrode 5 had a thickness of 0.12 μm. The thickness and bismuth concentration of the low-nickel concentration layer 3a in the semiconductor device were measured with a commercially available energy dispersive X-ray spectrometer. As a result, the low-nickel concentration layer 3a formed on the front-side electrode 2 had a thickness of 0.04 μm and a bismuth concentration of 600 ppm on average. The low-nickel concentration layer 3a formed on the back-side electrode 5 had a thickness of 0.03 μm and a bismuth concentration of 600 ppm on average.

As a result of directly soldering a metal electrode to the electroless gold plating layer 4 of the obtained semiconductor device in order to simulate the mounting step, the soldering quality was satisfactory. It is conceivable from the foregoing that the semiconductor device having high joining reliability was able to be manufactured.

### Comparative Example 1

A semiconductor device was obtained in the same manner as in Example 1 except that an acidic electroless nickel-phosphorus plating solution having no bismuth added thereto was used instead of the acidic electroless nickel-phosphorus plating solution (bismuth concentration: 50 ppm) used in the electroless nickel-phosphorus plating treatment in Example 1.

The thicknesses of the electroless nickel-containing plating layer 3 and the electroless gold plating layer 4 in the obtained semiconductor device were each measured with a commercially available fluorescent X-ray thickness meter. As a result, the electroless nickel-containing plating layer 3 had a thickness of 5.0 μm, and the electroless gold plating layer 4 had a thickness of 0.03 μm. The thickness of the low-nickel concentration layer 3a in the semiconductor device was measured with a commercially available energy dispersive X-ray spectrometer. As a result, the low-nickel concentration layer 3a had a thickness of 0.3 μm.

As a result of directly soldering a metal electrode to the electroless gold plating layer 4 of the obtained semiconductor device in order to simulate the mounting step, the wettability between the electroless gold plating layer 4 and the solder was unsatisfactory.

### EXPLANATION ON NUMERALS

1 front-back conduction-type semiconductor element
2 front-side electrode
3 electroless nickel-containing plating layer
3a low-nickel concentration layer
4 electroless gold plating layer
5 back-side electrode
6 protective film

1.-15. (canceled)

16. A semiconductor device, comprising:
a front-back conduction-type semiconductor element;
a front-side electrode formed on the front-back conduction-type semiconductor element;
an electroless nickel-containing plating layer formed on the front-side electrode; and
an electroless gold plating layer formed on the electroless nickel-containing plating layer,
wherein the semiconductor device has a low-nickel concentration layer on a side of the electroless nickel-containing plating layer in contact with the electroless gold plating layer, and the low-nickel concentration layer has a thickness smaller than a thickness of the electroless gold plating layer.

17. A semiconductor device, comprising:
a front-back conduction-type semiconductor element;
a front-side electrode formed on a front-side surface of the front-back conduction-type semiconductor element;
a back-side electrode formed on a back-side surface of the front-back conduction-type semiconductor element;
an electroless nickel-containing plating layer formed on each of the front-side electrode and the back-side electrode; and
an electroless gold plating layer formed on each of the electroless nickel-containing plating layers,
wherein the semiconductor device has a low-nickel concentration layer on a side of the electroless nickel-containing plating layer in contact with the electroless gold plating layer, and the low-nickel concentration layer has a thickness smaller than a thickness of the electroless gold plating layer.

18. The semiconductor device according to claim 16, wherein the low-nickel concentration layer contains at least one kind of gold deposition-promoting element selected from the group consisting of bismuth, thallium, lead, and arsenic.

19. A semiconductor device, comprising:
a front-back conduction-type semiconductor element;
a front-side electrode formed on the front-back conduction-type semiconductor element;
an electroless nickel-containing plating layer formed on the front-side electrode; and
an electroless gold plating layer formed on the electroless nickel-containing plating layer,
wherein the semiconductor device has at least one kind of gold deposition-promoting element selected from the group consisting of bismuth, thallium, lead, and arsenic at an interface between the electroless nickel-containing plating layer and the electroless gold plating layer.

20. A semiconductor device, comprising:
a front-back conduction-type semiconductor element;
a front-side electrode formed on a front-side surface of the front-back conduction-type semiconductor element;
a back-side electrode formed on a back-side surface of the front-back conduction-type semiconductor element;
an electroless nickel-containing plating layer formed on each of the front-side electrode and the back-side electrode; and
an electroless gold plating layer formed on each of the electroless nickel-containing plating layers,
wherein the semiconductor device has at least one kind of gold deposition-promoting element selected from the group consisting of bismuth, thallium, lead, and arsenic at an interface between the electroless nickel-containing plating layer and the electroless gold plating layer.

21. The semiconductor device according to claim 16,
wherein the front-side electrode is formed of aluminum, an aluminum alloy, or copper, and
wherein the electroless nickel-containing plating layer is formed of nickel phosphorus or nickel boron.

22. The semiconductor device according to claim 17,
wherein the front-side electrode and the back-side electrode are each formed of aluminum, an aluminum alloy, or copper, and
wherein the electroless nickel-containing plating layer is formed of nickel phosphorus or nickel boron.

23. A method of manufacturing a semiconductor device, comprising the steps of:
forming a front-side electrode on one side of a front-back conduction-type semiconductor element;
forming an electroless nickel-containing plating layer on the front-side electrode through use of an electroless nickel-containing plating solution; and
forming an electroless gold plating layer on the electroless nickel-containing plating layer through use of an electroless gold plating solution,
wherein the electroless nickel-containing plating solution contains at least one kind of gold deposition-promoting element selected from the group consisting of bismuth, thallium, lead, and arsenic.

24. A method of manufacturing a semiconductor device, comprising the steps of:
forming a front-side electrode and a back-side electrode on a front-back conduction-type semiconductor element;
forming electroless nickel-containing plating layers simultaneously on the front-side electrode and the back-side electrode through use of an electroless nickel-containing plating solution; and
forming electroless gold plating layers simultaneously on the respective electroless nickel-containing plating layers through use of an electroless gold plating solution,
wherein the electroless nickel-containing plating solution contains at least one kind of gold deposition-promoting element selected from the group consisting of bismuth, thallium, lead, and arsenic.

25. The method of manufacturing a semiconductor device according to claim 23, wherein the electroless nickel-containing plating solution contains the gold deposition-promoting element at a concentration of 0.01 ppm or more and 100 ppm or less.

26. The method of manufacturing a semiconductor device according to claim 23, wherein the step of forming the electroless nickel-containing plating layer comprises, immediately before completion of the step, segregating the gold deposition-promoting element on a surface layer of the electroless nickel-containing plating layer by increasing a supply amount of the electroless nickel-containing plating solution, increasing a stirring rate of the electroless nickel-containing plating solution, increasing rocking of the electroless nickel-containing plating solution, or increasing a concentration of the gold deposition-promoting element in the electroless nickel-containing plating solution.

27. The method of manufacturing a semiconductor device according to claim 23, wherein the step of forming the electroless nickel-containing plating layer on the front-side electrode is performed after the front-side electrode formed of aluminum or an aluminum alloy is subjected to zincate treatment.

28. The method of manufacturing a semiconductor device according to claim 24, wherein the step of forming the electroless nickel-containing plating layers simultaneously on the front-side electrode and the back-side electrode is performed after the front-side electrode formed of aluminum or an aluminum alloy and the back-side electrode formed of aluminum or an aluminum alloy are simultaneously subjected to zincate treatment.

29. The method of manufacturing a semiconductor device according to claim 23, wherein the step of forming the electroless nickel-containing plating layer on the front-side electrode is performed after the front-side electrode formed of copper is subjected to palladium catalyst treatment.

30. The method of manufacturing a semiconductor device according to claim 24, wherein the step of forming the electroless nickel-containing plating layers simultaneously on the front-side electrode and the back-side electrode is performed after the front-side electrode formed of copper and the back-side electrode formed of copper are simultaneously subjected to palladium catalyst treatment.

31. The semiconductor device according to claim 17, wherein the low-nickel concentration layer contains at least one kind of gold deposition-promoting element selected from the group consisting of bismuth, thallium, lead, and arsenic.

32. The semiconductor device according to claim 19,
wherein the front-side electrode is formed of aluminum, an aluminum alloy, or copper, and
wherein the electroless nickel-containing plating layer is formed of nickel phosphorus or nickel boron.

33. The semiconductor device according to claim 20,
wherein the front-side electrode and the back-side electrode are each formed of aluminum, an aluminum alloy, or copper, and
wherein the electroless nickel-containing plating layer is formed of nickel phosphorus or nickel boron.

34. The method of manufacturing a semiconductor device according to claim 24, wherein the electroless nickel-containing plating solution contains the gold deposition-promoting element at a concentration of 0.01 ppm or more and 100 ppm or less.

35. The method of manufacturing a semiconductor device according to claim 24, wherein the step of forming the electroless nickel-containing plating layer comprises, immediately before completion of the step, segregating the gold deposition-promoting element on a surface layer of the electroless nickel-containing plating layer by increasing a supply amount of the electroless nickel-containing plating solution, increasing a stirring rate of the electroless nickel-containing plating solution, increasing rocking of the electroless nickel-containing plating solution, or increasing a concentration of the gold deposition-promoting element in the electroless nickel-containing plating solution.
